(19) United States
(12) Patent Application Publication
(10) Pub. No.: US 2016/0380317 A1
(43) Pub. Date: Dec. 29, 2016

(54) METHOD AND SYSTEM FOR MONITORING BATTERY CELL HEALTH

(71) Applicant: Amphenol Thermometrics, Inc., St. Marys, PA (US)

(72) Inventors: Yizhen Lin, Niskayuna, NY (US); Aaron Jay Knobloch, Niskayuna, NY (US); Christopher James Kapusta, Niskayuna, NY (US); Jason Harris Karp, Niskayuna, NY (US)

(21) Appl. No.: 14/832,330

(22) Filed: Aug. 21, 2015

Related U.S. Application Data
(60) Provisional application No. 62/183,988, filed on Jun. 24, 2015.
(60) Provisional application No. 62/184,617, filed on Jun. 25, 2015.

(51) Int. Cl. H01M 10/48; G01L 1/18; G01R 31/36

(52) U.S. Cl. CPC H01M 10/482; G01R 31/3679; G01R 31/362; G01L 1/18

(57) ABSTRACT

A strain sensor, a system for monitoring a state of a battery cell, and a battery including the strain sensor. The strain sensor includes a thin, flexible substrate, a plurality of piezoresistors mounted on the substrate, an input for receiving a voltage signal, an output for providing an output voltage signal from the plurality of piezoresistors. The plurality of piezoresistors are connected to form a circuit that is insensitive to a change in temperature and an in-plane deformation of the substrate. The system includes the strain sensor, a source of voltage, and an analysis module configured for receiving a voltage signal based on the output voltage signal provided at the output of the strain sensor and calculating a state of charge or a state of health of a battery cell based on the received voltage signal. The battery includes the strain sensor and a space for spacing adjacent battery cells.

### CROSS REFERENCE TO RELATED APPLICATIONS

This application claims the benefit of U.S. Provisional Application No. 62/183,988, entitled “Method and System for Monitoring Battery Cell Health” and filed Jun. 24, 2015, and the benefit of U.S. Provisional Application No. 62/184,617, entitled “Method and System for Monitoring Battery Cell Health” and filed Jun. 25, 2015, the contents of which applications are incorporated herein by reference.

### STATEMENT OF GOVERNMENT RIGHTS

This invention was made with Government support under Award Number DE-AR0000269 awarded by U.S. Department of Energy. The Government has certain rights in this invention.

### FIELD OF THE INVENTION

The present invention relates to a system and method for monitoring battery cell health and, more specifically, to a system and method for measuring strain in a wall of a battery cell and/or a string of battery cells in a battery pack and calculating a state of health for the battery cell based on the measured strain.

### BACKGROUND OF THE INVENTION

Electrochemical storage devices, such as batteries and capacitors, are found in many electrical devices, e.g., cell phones, laptops, etc., and power generation systems, such as those found in automobiles in regenerative breaks and those found at power stations for grid storage. Typically, in automotive battery packs used in plug-in hybrid electric vehicles (PHEVs), hybrid electric vehicles (HEVs) or battery electric vehicles (BEVs) comprise a plurality of cells packaged in a module. One or more modules may be arranged within a pack.

FIG. 1A shows an arrangement of a conventional battery 100 comprising a plurality of prismatic cells 110. FIG. 1B illustrates a detail view of a group 115 of the cells 110.

Referring to FIGS. 1A and 1B, each cell 110 comprises an outer package or wall 112 and at least two electrodes 114A and 114B. The cells 110 may be formed from one of any number of chemistries, including Li-ion, which is a typical chemistry in automobile battery packs in a variety of electric vehicle (EV) applications. Various embodiments of the outer wall 112 are contemplated. The outer wall 112 may be a thin metallic outer case (usually in rectangular form) called a soft pouch cell enclosing the electrodes and electrolyte, or it may be a thicker metallic outer case (either in cylindrical or prismatic (rectangular cross-section) form) called a hard pouch cell enclosing the electrodes and electrolyte. FIGS. 1A and 1B illustrate the exemplary embodiment of the outer wall 112 of each cell 110 embodied as a hard pouch cell. It is to be understood that the outer wall 112 is not so limited may be embodied as any of the other embodiments described above.

Many of the commercial EV packs that exist today are designed around their cooling systems. Some packs are air cooled using cabin air that flows between the cells to maintain a constant uniform temperature across the cells and cool them. Other EV packs are water cooled. In some implementations of air cooled prismatic packs, spacers maintain the cells at a distance from one another to allow for air to pass over the surface of the cells to cool them and maintain temperature uniformity across the pack. In other implementations, e.g., in EV packs having cylindrical cells, the cells are held from above and below to maintain the cells at a distance from one another to allow air to pass around the cells to cool them. In water cooled configurations, water passes around the exterior of the cell in either cylindrical or prismatic implementations. The important function of the cooling is to optimize the performance of the cells by operating them at a preferred temperature and to prevent thermal runaway and damage from operating at elevated temperatures.

As the cells 110 are charged and discharged, the outer wall 112 of the cells 110 expand and contract. One cause is the temperature change that arises within the cell 110 due to the electrochemical process or outside of the cells 110 due to the environment. In embodiments in which the cells are lithium ion cells, lithiation of the electrodes 114 also causes the outer walls 112 of the cells 110 to expand and contract. Expansion and contraction the outer walls 112 of the cells 110 is a unique parameter based on the electrode 114 composition and cell 110 chemistry. Expansion of the outer walls 112 of the cells 110 could lead to the outer walls 112 of the cells 110 in the conventional battery pack 100 coming into contact with one another and shorting, in the case in which the outer walls 112 are conductive. Such contact would cause a battery fault. Excessive expansion can lead to cell leakage, or destructive failure with cell pack “run-away”.

Battery management systems (BMS) today make voltage, current, and limited temperature measurements to monitor the health of the battery pack 100 on the cell 110 level. A better understanding of the state of health (SOH) and state of charge (SOC) of the battery 100 can lead to smaller factors of safety in the design of the battery 100. The amount of expansion at any particular SOC is a function of the cell 110 temperature and health or remaining life of the cell 110.

Accurate in situ measurements of parameters of the cell 110, such as strain or even wall 112 temperature, cannot be performed between the cells 110 because accurate conventional sensor systems are too thick and bulky. In prior work, researchers have examined the deflection of the cells 110 using neutron scattering measurements of the electrodes 114 themselves or laser-based-measurements of the deflections of the outer walls 112 of the cells 110. These techniques are not possible for in situ measurements that can be fielded in an automotive application.

In situ measurements of the deflection of the outer walls 112 of the cells 110 when the cells 110 are packaged as part of a pack 100 that would be suitable for field installation either in grid storage or on-road vehicle applications are desirable. One conventional strain measurement technique that can be disposed between the cells 110 for in-site measurement uses a stand-alone piezoresistor. A stand-alone piezoresistor is disadvantageous because its resistance varies with temperature. Signal change caused by temperature can be 20× the signal change caused by the strain due to the differences in Temperature Coefficient of Resistance and the Gage factor of the piezoresistor. The variation in output depending on temperature makes determining strain from the output of a piezoresistor difficult due to the low output at full scale strain levels. Additionally, a conventional piezoresistor is more sensitive to in-plane strain than to out-of-plane strain experienced due to the bending of the cell during charging and discharging. To improve the understanding of the SOH and SOC of a cell 110, the bending (out-of-plane) strain, or swelling of the cell 110 caused by charging and discharging is desirably monitored with a sensor that has a small form factor that can be fielded in an automotive application.

### SUMMARY OF THE INVENTION

In accordance with an aspect of the present invention, there is provided a strain sensor comprising a thin, flexible substrate, a plurality of piezoresistors mounted on the substrate, an input for receiving a voltage signal, and an output for providing an voltage signal from the plurality of piezoresistors. The plurality of piezoresistors is connected to form a circuit that is insensitive to a change in temperature.

In accordance with another aspect of the present invention, there is provided a system for monitoring a state of a battery cell. The system comprises a source of voltage, a strain sensor, and a signal analysis module. The strain sensor comprises a thin, flexible substrate, a plurality of piezoresistors deposited on the substrate, an input for receiving a voltage from the source of voltage, and an output for providing an voltage signal from the plurality of piezoresistors. The plurality of piezoresistors is connected to form a circuit that is insensitive to a change in temperature. The signal analysis module is configured for receiving a voltage signal based on the output voltage signal provided at the output of the strain sensor, and calculating a state of charge or a state of health of a battery cell based on the received voltage signal.

In accordance with yet another exemplary embodiment of the present invention, there is provided a battery assembly comprising a mechanical spacer comprising at least one horizontal member, a first battery cell comprising a first wall, a second battery cell comprising a first wall spaced from the first wall of the first battery cell by the spacer, and a strain sensor. At least a portion of the strain sensor is disposed on the first wall of the first battery cell. The strain sensor comprises a thin, flexible substrate, a plurality of piezoresistors mounted on the substrate, an input for receiving a voltage signal, and an output for providing an output voltage signal from the plurality of piezoresistors. The plurality of piezoresistors is connected to form a circuit that is insensitive to a change in temperature.

### BRIEF DESCRIPTION OF THE DRAWINGS

For the purpose of illustration, there are shown in the drawings certain embodiments of the present invention. In the drawings, like numerals indicate like elements throughout. It should be understood that the invention is not limited to the precise arrangements, dimensions, and instruments shown. In the drawings:

FIG. 1A illustrates a conventional battery pack comprising a plurality of cells;

FIG. 1B illustrates a detail view of a group of the plurality of cells of FIG. 1A;

FIG. 2 illustrates a battery comprising a plurality of cells spaced apart by respective spacers, and a strain sensor disposed on an outside wall of one of the plurality of cells, in accordance with an exemplary embodiment of the present invention;

FIG. 3A illustrates a close-up view of the strain sensor of FIG. 2 comprising a plurality of piezoresistors, the strain sensor subject to no bending strain; in accordance with an exemplary embodiment of the present invention;

FIG. 3B illustrates a close-up view of the strain sensor of FIG. 2 subject to a bending strain; in accordance with an exemplary embodiment of the present invention;

FIG. 4 illustrates one of the piezoresistors of FIG. 3, in accordance with an exemplary embodiment of the present invention;

FIG. 5 illustrates a schematic view of the strain sensor of FIG. 2, wherein the piezoresistors are shown connected as a Wheatstone bridge, in accordance with an exemplary embodiment of the present invention;

FIG. 6A illustrates an exemplary embodiment of a system for measuring strain present on the outside wall of one of the plurality of cells of FIG. 2, in accordance with an exemplary embodiment of the present invention;

FIG. 6B illustrates the embodiment shown in FIG. 6A with the an embodiment of a sensor measuring strain present on the outside wall of one of the plurality of cells of FIG. 2, in accordance with an exemplary embodiment of the present invention;

FIG. 6C illustrates the embodiment shown in FIG. 6A with the an embodiment of a sensor measuring strain present on the outside wall of one of the plurality of cells of FIG. 2 and temperature of the outside wall of one of the plurality of cells of FIG. 2, in accordance with an exemplary embodiment of the present invention;

FIGS. 7A through 7C illustrate an exemplary embodiment of the strain sensor of FIG. 3, in accordance with an exemplary embodiment of the present invention;

FIG. 7D illustrates another exemplary embodiment of the strain sensor of FIG. 3, in accordance with an exemplary embodiment of the present invention;

FIG. 8 illustrates an exemplary placement of the strain sensor of FIGS. 7A through 7C on an outside wall of a battery cell, in accordance with an exemplary embodiment of the present invention; and

FIG. 9 illustrates measured voltages and calculated bending strain from a test performed on a prototype of the strain sensor of FIGS. 7A through 7C, in accordance with an exemplary embodiment of the present invention.

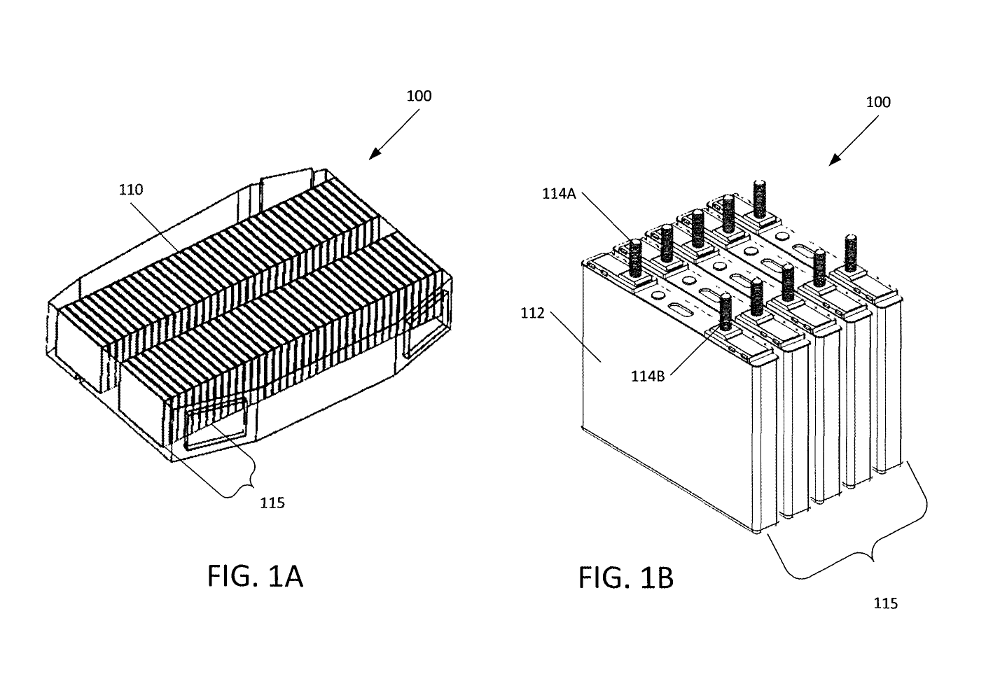

### DETAILED DESCRIPTION OF THE INVENTION

Reference to the drawings illustrating various views of exemplary embodiments of the present invention is now made. In the drawings and the description of the drawings herein, certain terminology is used for convenience only and is not to be taken as limiting the embodiments of the present invention. Furthermore, in the drawings and the description below, like numerals indicate like elements throughout.

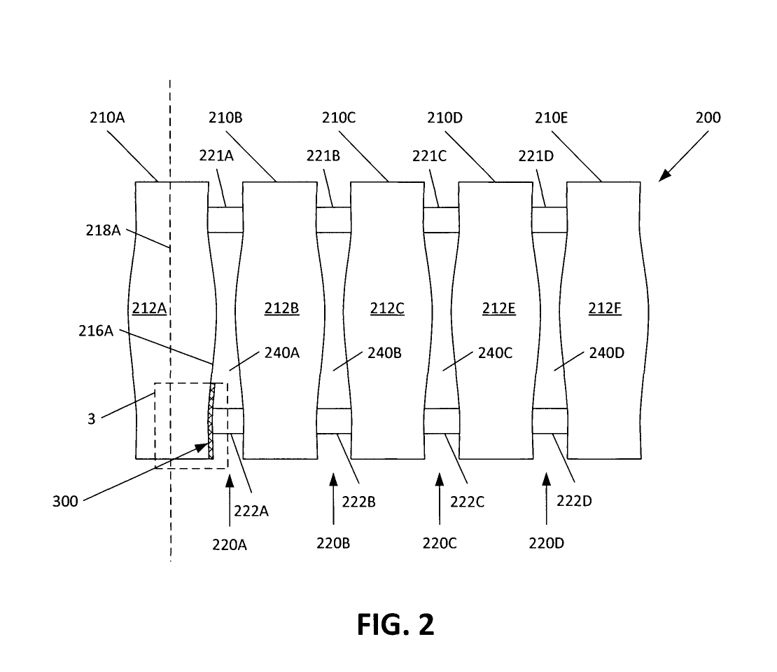

Referring now to FIG. 2, there is illustrated a battery 200 comprising a plurality of cells 210A, 210B, 210C, 210D, and 210E, in accordance with an exemplary embodiment of the present invention. Each of the cells 210A, 210B, 210C, 210D, and 210E comprises a respective case 212A, 212B, 212C, 212D, and 212E, the outer walls of which are illustrated as bending outwardly. The cells 210A, 210B, 210C, 210D, and 210E may be formed from one of any number of chemistries, including lithium ion. Adjacent cells 210 are spaced apart by a spacer 220 comprising a plurality of horizontal members 221 and 222. Thus, the cells 210A and 210B are spaced apart by a spacer 220A comprising horizontal members 221A and 222A; the cells 210B and 210C are spaced apart by a spacer 220B comprising horizontal members 221B and 222B; the cells 210C and 210D are spaced apart by a spacer 220C comprising horizontal members 221C and 222C; and the cells 210D and 210E are spaced apart by a spacer 220D comprising horizontal members 221D and 222D.

The spacers 220 maintain gaps between the cells 210. Thus, between the cells 210A and 210B is a space 240A. Between the cells 210B and 210C is a space 240B. Between the cells 210C and 210D is a space 240C. Between the cells 210D and 210E is a space 240D.

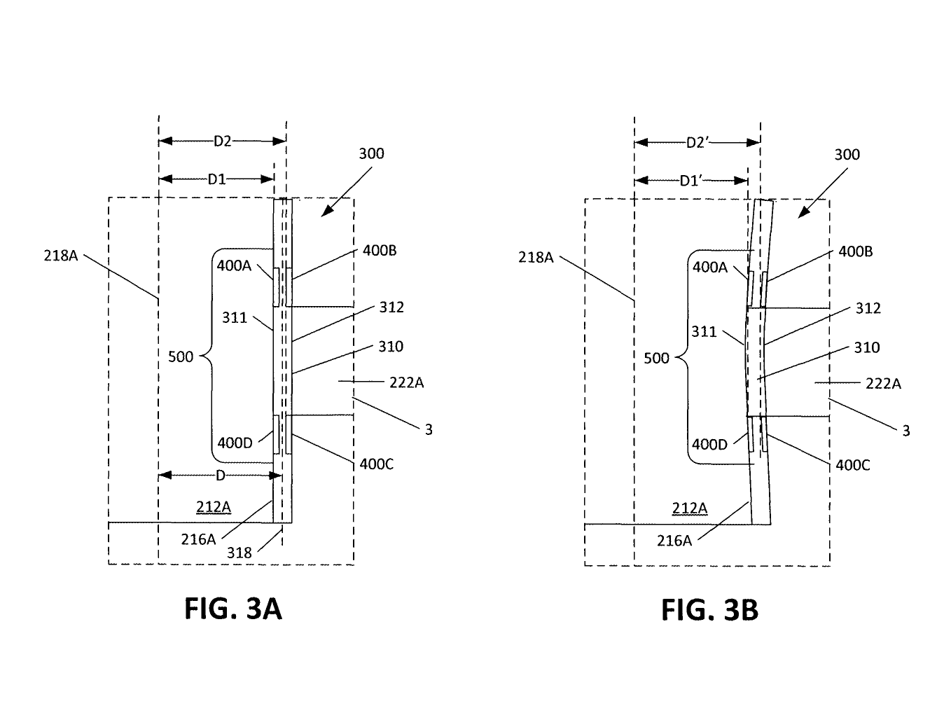

A strain sensor 300 is disposed on the case 212A of the cell 210A on an outside surface 216A of the case 212A facing the space 240A. The outside surface 216A is shown bending outwardly with respect to a neutral axis 218A of the cell 210A. The neutral axis 218A of the cell 210A describes the plane of the cell 210A which does not move as the cell 210A expands, which expansion causes the outside surface 216A of the cell 210A to bend outwardly. FIGS. 3A and 3B provide close-up views of an area 3 (illustrated in FIG. 2) of the battery 200 and specifically of the strain sensor 300, in accordance with an exemplary embodiment of the present invention. FIG. 3A illustrates the strain sensor 300 when the outside surface 216A of the case 212A of the cell 210A is not bending outwardly. FIG. 3B illustrates the strain sensor 300 when the outside surface 216A of the case 212A of the cell 210A is bending outwardly.

With reference to FIGS. 3A and 3B, the strain sensor 300 comprises a substrate 310 and a plurality of piezoresistors 400A, 400B, 400C, and 400D deposited on the substrate 310. The inner piezoresistors 400A and 400D are mounted on an inside surface 311 of the substrate 310, and the outer piezoresistors 400B and 400C are mounted on an outside surface 312 of the substrate 310. As illustrated, the substrate 310 comprises a centerline 318. The distance of each of the piezoresistors 400A and 400D to the centerline 318 is equal to the distance of each of the piezoresistors 400B and 400C to the centerline 318. The piezoresistors 400A through 400D may be formed from platinum, silicon, polysilicon, conductive inks, etc. The substrate may be formed from any material that desirably has a coefficient of thermal expansion that matches that of the case 212A of the cell 210A. Such materials may be polyimide, mylar, metallic with insulators, glass, plastic, etc.

Although piezoresistors 400A through 400D are illustrated and described herein, it is contemplated that other components may be used as in place of the piezoresistors 400A through 400D for detecting a change in resistance due to mechanical strain. For example, the components 400A, 400B, 400C, and 400D may each be embodied as a polymer including conductive particles. Alternatively, the components 400A, 400B, 400C, and 400D may each be embodied as conductive inks deposited on the substrate 310.

The strain sensor 300 is positioned on the outside surface 216A of the case 212A so that the pair of the piezoresistors 400B and 400C straddle the horizontal member 222A of the spacer 220. Specifically, the strain sensor 300 is positioned so that the outside surface 312 of the substrate 310 is in contact with the horizontal member 222A of the spacer 220. Thus, the piezoresistor 400B is positioned to be above but immediately adjacent to or touching the horizontal member 222A, and the piezoresistor 400C is positioned to be below but immediately adjacent to or touching the horizontal member 222A. The piezoresistors 400A and 400D have the same vertical distance relative to the horizontal member 222A as the piezoresistors 400B and 400C, respectively, although they are mounted on the inside surface 311 of the substrate 310. Thus, the bottom of the piezoresistor 400A is vertically aligned with the bottom of the piezoresistor 400B, and the top of the piezoresistor 400D is vertically aligned with the top of the piezoresistor 400C. The piezoresistors 400A through 400D are positioned on the substrate 310, vertically spaced relative to the horizontal member 222A, and aligned with a high bending moment present in the case 212A. The piezoresistors 400A through 400D are vertically positioned on the substrate 310 to be close to the horizontal member 222A to maximize the bending moment they are subject to. Specifically, the piezoresistors 400A through 400D are so positioned so that they are located at the maximum bending stress on the outside surface 216A of the case 212A and thus the maximum stress that is recognized by the outside surface 216A. Thus, the position of the piezoresistors 400A through 400D provides the best indication of the contraction and expansion of, and distance travelled by, the outside surface 216A of the case 212A.

The substrate 310 is attached to the surface 216A of the outer housing or case 212A. Thus, the substrate 310 conforms to the shape of the surface 216A of the case 212A. The strain sensor 300 is configured to detect an out-of-plane deflection of the surface 216A of the case 212A resulting from the surface 216A of the case 212A expanding or contracting due to temperature variations or lithiation (in embodiments in which the battery cell 210A incorporates a lithium ion chemistry). In an exemplary embodiment, the substrate 310 is attached to the case 212A by an adhesive, such as an epoxy. In an exemplary embodiment, the substrate 310 is ultrathin and may be less than 100 μm thick. Because of the thin width of the substrate 310, exemplary embodiments in which the strain sensor 300 is mounted on an inside surface of the case 212 of the cell 210A are contemplated.

FIG. 3A illustrates the strain sensor 300 when it is not subject to bending stress. As shown, centerline 318 of the substrate 310 is offset from the centerline 218 of the cell 210A by a distance D. Thus, the piezoresistors 400A, 400B, 400C, and 400D are offset from the centerline 218 of the cell 210A, the piezoresistors 400A and 400D being offset from the neutral axis 218A by a distance D1, and the piezoresistors 400B and 400C being offset from the neutral axis 218A by a distance D2. FIG. 3B illustrates the strain sensor 300 when it is subject to bending stress. As shown, the piezoresistors 400A and 400D are offset from the neutral axis 218A by a distance D1′, and the piezoresistors 400B and 400C are offset from the neutral axis 218A by a distance D2′. Because of the difference in the offsets, the piezoresistors 400A through 400D detect different strain measurements as they are subject to different bending (out-of-plane) stresses. Specifically, because D2 (and D2′) is greater than D1 (and D1′), the piezoresistors 400B and 400C are subject to greater bending stresses than the piezoresistors 400A and 400D as the piezoresistors 400B and 400C are further from the neutral axis 218A. As discussed below, the difference in strain detected by the piezoresistors 400B and 400C compared to the piezoresistors 400A and 400D allows the amount of bending in the outside surface 216A of the case 212A of the cell 210A to be estimated. To increase the difference in strain detected by the piezoresistors 400B and 400C compared to the piezoresistors 400A and 400D, the thickness of the substrate 310 may be increased.

As noted above, a conventional piezoresistor mounted on a battery cell wall suffers from a number of disadvantages. Signal change caused by temperature can be 20× the signal change caused by the strain due to the differences in Temperature Coefficient of Resistance and the Gage factor of the piezoresistor. The variation in output depending on temperature makes determining strain from the output of the piezoresistor difficult due to the low output at full scale strain levels. Additionally, a conventional piezoresistor is more sensitive to in-plane strain than to out-of-plane strain experienced due to the bending of the cell during charging and discharging.

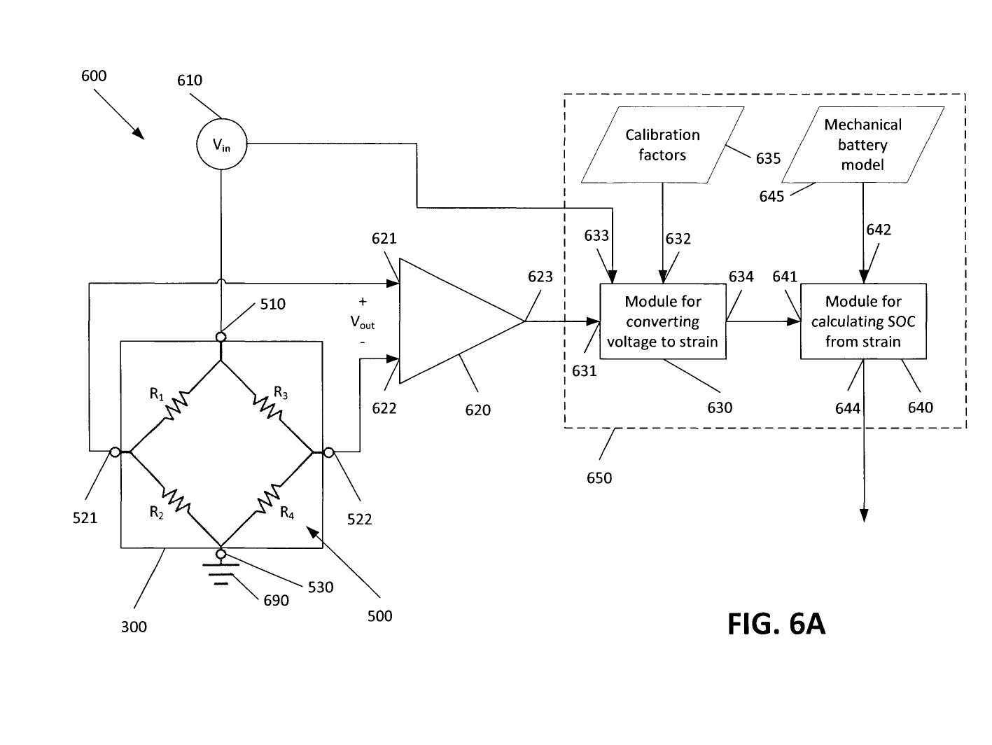

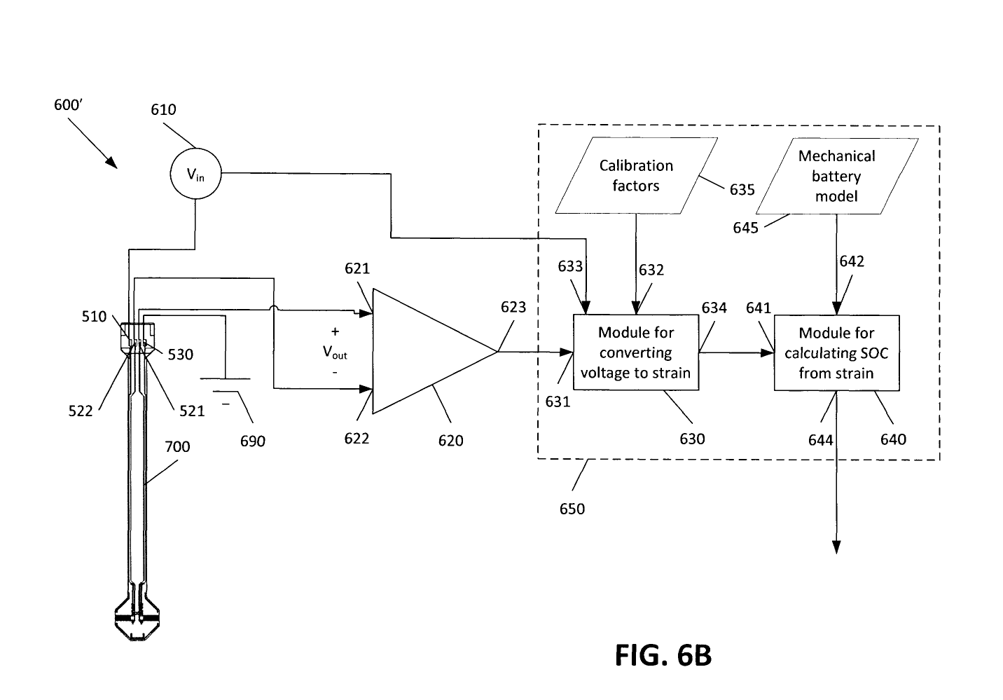

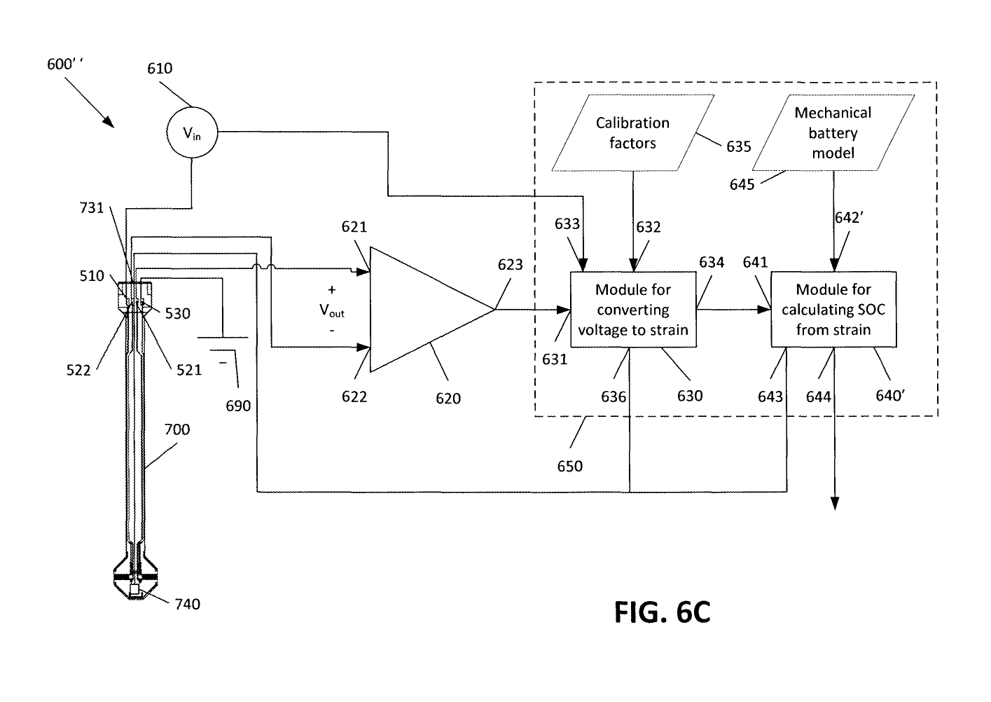

The strain sensor 300 addresses the problems posed by the conventional piezoresistor. It is significantly more sensitive to out-of-plain strain experienced due to the bending of the cell 210A during charging and discharging than the conventional piezoresistor, is insensitive to in-plane strain, and is insensitive to temperature change. In-plane stresses in the strain sensor 300 affect the piezoresistors 400A and 400D the same. Temperature changes in the strain sensor 300 also affect the piezoresistors 400A and 400D the same. As described below with reference to FIGS. 5 and 6A, the connection of the piezoresistors 400A through 400D as a Wheatstone bridge 500 minimize the effects of in-plane strain and temperature change on the piezoresistors 400A and 400D.

Out-of-plane stresses in the strain sensor 300 do not affect the piezoresistors 400A and 400D the same because the piezoresistors 400B and 400C are located further from the neutral axis 218A than the piezoresistors 400A and 400D and are, therefore, subject to greater bending stresses than the piezoresistors 400A and 400D. Thus, whereas the conventional piezoresistor is relatively insensitive to bending strain, the piezoresistors 400A through 400D when connected as a Wheatstone bridge 500 are significantly more sensitive to out-of-plane strain than the conventional piezoresistor.

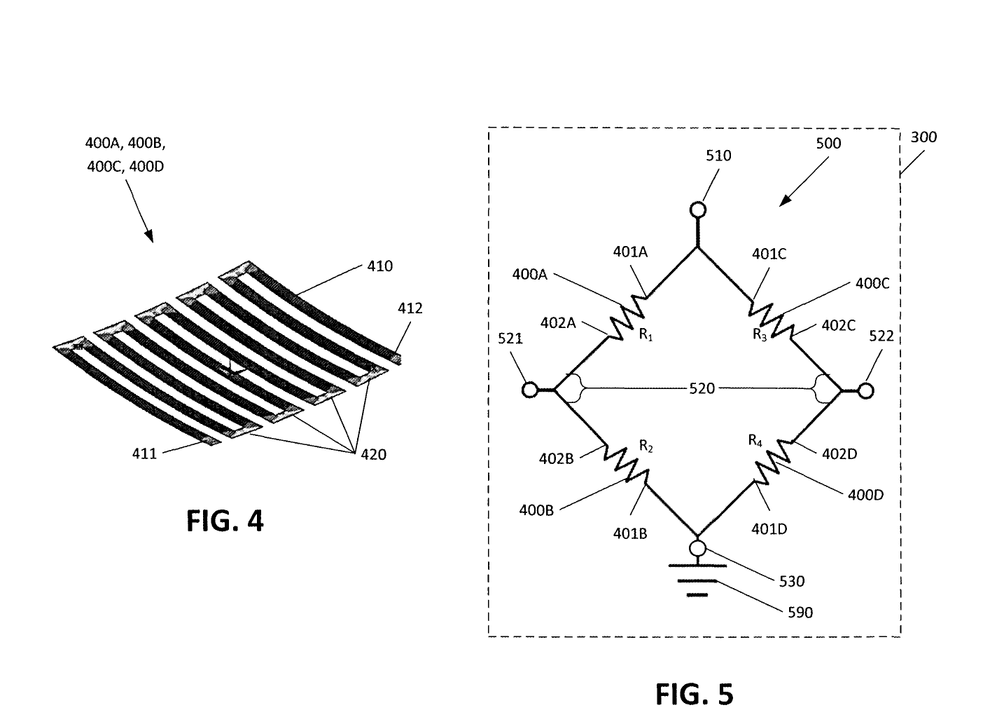

As seen in FIG. 4, each piezoresistor 400 comprises a resistive conductor 410 comprising a first terminal 411, a second terminal 412, and a plurality of windings 420 extending from the first terminal 411 to the second terminal 412. Each piezoresistor 400 is designed to have a high number of windings 420 to increase its length. The longer the piezoresistor 400 is, the more sensitive it is in a direction of bending moment. In the illustrated embodiment, the piezoresistors 400A, 400B, 400C, and 400D are electrically connected in the strain sensor 300 as a Wheatstone bridge 500. Another view of the strain sensor 300 showing the connection of the piezoresistors 400A, 400B, 400C, and 400D to form the Wheatstone bridge 500 is illustrated in FIG. 5, in accordance with an exemplary embodiment of the present invention. The Wheatstone bridge 500 comprises the piezoresistors 400A, 400B, 400C, and 400D, an input 510, an output 520, and a terminal 530. The output 520 comprises the electric potential difference between the first output terminal 521 and a second output terminal 522.

A first end 401A of the piezoresistor 400A and a first end 401C of the piezoresistor 400C are connected to the input 510. A first end 401 B of the piezoresistor 400B and a first end 401D of the piezoresistor 400D are connected to the terminal 530, which is connected to ground 590. A second end 402A of the piezoresistor 400A and a second end 402B of the piezoresistor 400B are connected to the first output terminal 521 of the output 520. A second end 402C of the piezoresistor 400C and a second end 402D of the piezoresistor 400D are connected to the second output terminal 522 of the output 520.

Expansion or contraction of the battery housing 212A causes the piezoresistors 400A and 400D on the inside surface 311 of the substrate 310 and the piezoresistors 400B and 400C on the outside surface 312 of the substrate 310 to change resistance in different amounts. In other words, as the battery housing 212A expands, the resistance of each of the piezoresistors 400A and 400D decreases by an amount, X1, and the resistance of the piezoresistors 400B and 400C decreases by an amount, X2, greater than X1. The output 520 of the Wheatstone bridge 500 can therefore be used to extract information regarding out-of-plane strain of the surface 216A of the case 212A indicative of out-of-plane expansion or contraction of the surface 216A of the case 212A. Because the piezoresistors 400A and 400D are mounted on the inside surface 311 of the substrate 310 and the piezoresistors 400B and 400C are mounted on the outside surface side 312 of the substrate 310 opposite the inside surface 311, temperature change or uniform stretching of the surface 216A of the case 212A and, therefore, of the substrate 310 of the strain sensor 300 cause the resistance of each of the piezoresistors 400A, 400B, 400C, and 400D to change by the same amount (having the same sign +/−), thereby resulting in no output from the Wheatstone bridge 500. The strain sensor 300 is, therefore, not sensitive to temperature change in either the cell 110A or the environment in which the cell 110A is found.

Referring now to FIG. 6A, there is illustrated a diagram of a system, generally designated as 600, for measuring strain present on the surface 216A of the case 212A of the cell 210A, in accordance with an exemplary embodiment of the present invention. The circuit 600 comprises the Wheatstone bridge 500, a signal source 610, an amplifier 620, and a signal analysis module 650. The signal source 610 powers the Wheatstone bridge 500. The

Wheatstone bridge 500 provides an output voltage signal indicative of strain. The amplifier 620 amplifies the voltage signal output by the Wheatstone bridge 500. The signal analysis module 650 comprises a module 630 for converting the amplified voltage signal to strain, a module 640 for converting from strain to an indication of a state of charge (SOC) and/or a state of health (SOH) of the battery cell 110, and an output 644 for outputting an indication of the SOC and/or

SOH. The amplifier 620 comprises inputs 621 and 622. The input 621 of the amplifier 620 is connected to the output terminal 521 of the Wheatstone bridge 500, and the input 622 of the amplifier 620 is connected to the output terminal 522 of the Wheatstone bridge 500. The terminal 530 of the Wheatstone bridge 500 is connected to ground 690.

The signal source 610 is connected to the input 510 of the Wheatstone bridge 500 and provides a voltage signal Vᵢₙ to the input 510 of the Wheatstone bridge 500. The amplifier 620 amplifies an output voltage Vₒᵤₜ between the output terminals 521, 522 of the Wheatstone bridge 500. In one exemplary embodiment, the signal source 610 may be a DC source providing a constant voltage and current to the input 510 of the Wheatstone bridge 500. In another exemplary embodiment, the signal source 610 may be an AC source providing a varying voltage and current to the input 510 of the Wheatstone bridge 500. In yet another exemplary embodiment, the signal source may be a pulsed DC source providing a signal, such as a square wave, thereby providing for low duty cycle operation for low power and limited self-heating of the piezoresistors 400A through 400D.

The ratio of Vₒᵤₜ to Vᵢₙ in the Wheatstone bridge 500 is given by equation (1):

$$\frac{{V}_{out}}{{V}_{in}} = \frac{{R}_{2} δ {R}_{1} - {R}_{1} δ {R}_{2}}{{( {R}_{1} + {R}_{2} )}^{2}} - \frac{{R}_{4} δ {R}_{3} - {R}_{3} δ {R}_{4}}{{( {R}_{3} + {R}_{4} )}^{2}} \qquad ( 1 )$$

Assuming that R₁=R₂=R₃=R₄, then equation (1) can be simplified as:

$$\frac{{V}_{out}}{{V}_{in}} ≅ \frac{δ {R}_{1} - δ {R}_{2} + δ {R}_{4} - δ {R}_{3}}{4 R} \qquad ( 2 )$$

When subject to temperature change, δR₁=δR₂ and δR₄=δR₃ and, therefore, Vₒᵤₜ=0. Thus, the strain sensor 300 and, specifically, the Wheatstone bridge 500 is not sensitive to changes in ambient temperature or changes in the cell 210A temperature.

The change in resistance of a piezoresistor can be written in terms of its gauge factor and strain as:

δRₓ=G_{f}εₓR, (3)

where G_{f} is the gauge factor, εₓ is the strain, and x=1, 2, 3, or 4 (corresponding to R₁ through R₄, respectively). Substituting equation (3) into equation (2) for each of δR₁ through δR₄ results in:

$$\frac{{V}_{out}}{{V}_{in}} ≅ \frac{{G}_{f} ( {ε}_{1} - {ε}_{2} + {ε}_{4} - {ε}_{3} )}{4 R} \qquad ( 4 )$$

Bending of the surface 216A of the battery cell 212A causes the piezoresistors 400B and 400C on the outside surface 312 of the substrate 310 to change resistance and for the piezoresistors 400A and 400D on the inside surface 311 of the substrate 310 to change resistance by different magnitude. This results in a non-zero Vₒᵤₜ, which can be used to extract strain information detected by the strain sensor 300.

The amplifier 620 receives Vₒᵤₜ at its inputs 621 and 622 and amplifies it to provide an amplified A Vₒᵤₜ at its output 623, where A is the gain of the amplifier 620. The amplified gain A Vₒᵤₜ is provided to the module 630. The module 630 receives the amplified gain A Vₒᵤₜ at an input 631, one or more calibration factors 635 at an input 632, and the reference voltage input Vᵢₙ via an input 633. The calibration factors include the gauge factor G_{f} for the piezoresistors R₁ through R₄. The module 630 calculates the total strain ε₁−ε₂+ε₄−ε₃ on the surface 216A of the case 212A of the cell 210A and outputs the calculated total strain ε₁−ε₂+ε₄−ε₃ at a strain output 634.

The module 640 receives the total strain ε₁−ε₂+ε₄−ε₃ at an input 641 and a mechanical battery model 645 at an input 642. Using the total strain ε₁−ε₂+ε₄−ε₃ and the mechanical battery model 645, the circuitry 640 calculates a SOC and/or a SOH for the battery cell 210A. The module 640 provides the calculated SOC and/or SOH at an SOC/SOH output 644. The output 644 forms the output of the signal analysis module 650.

In an exemplary embodiment, the piezoresistors 400A through 400D are formed from platinum, and R₁=R₂=R₃=R₄=100 ohm. The gage factor G_{f} of Pt=6. Under an exemplary stress, the measured bending strain is 35 micro-strain. This will produce a voltage output of around 2.5 mV at the output 520 with excitation voltage at the input terminal 510 of 12V. The resistance change of the piezoresistors 400A through 400D is 0.02 ohm.

In an exemplary embodiment of the system 600, at least one of the piezoresistors 400A through 400D of the Wheatstone bridge 500 is used for measuring temperature. In such embodiment, the system 600 may be used to calculate a SOH or SOC of the battery cell 210A based on strain measured by the Wheatstone bridge 500 and temperature measured by at least one of the piezoresistors 400A through 400D.

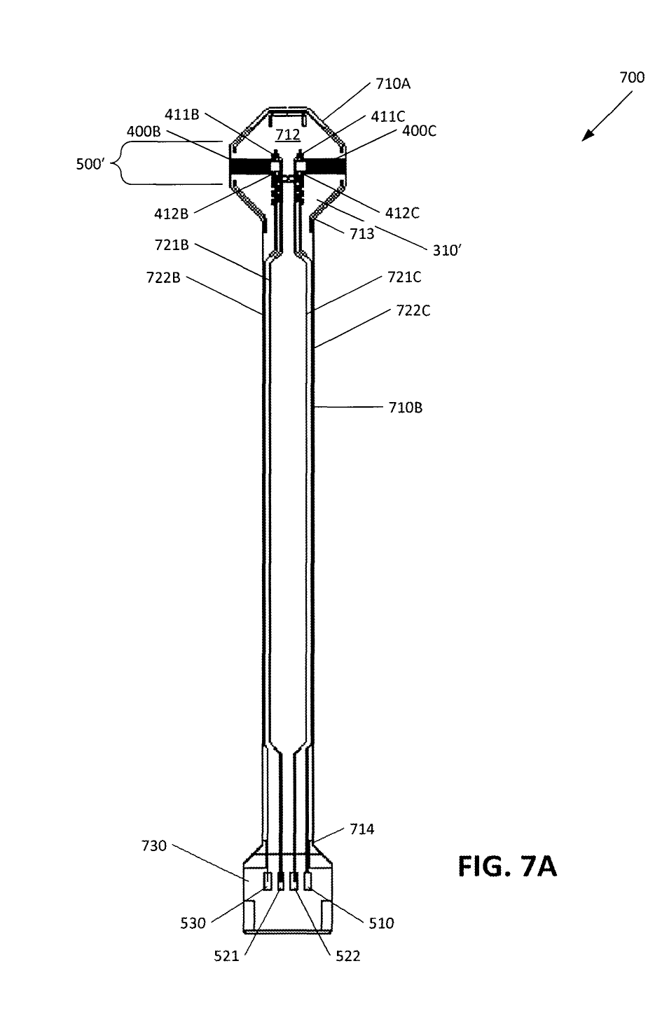

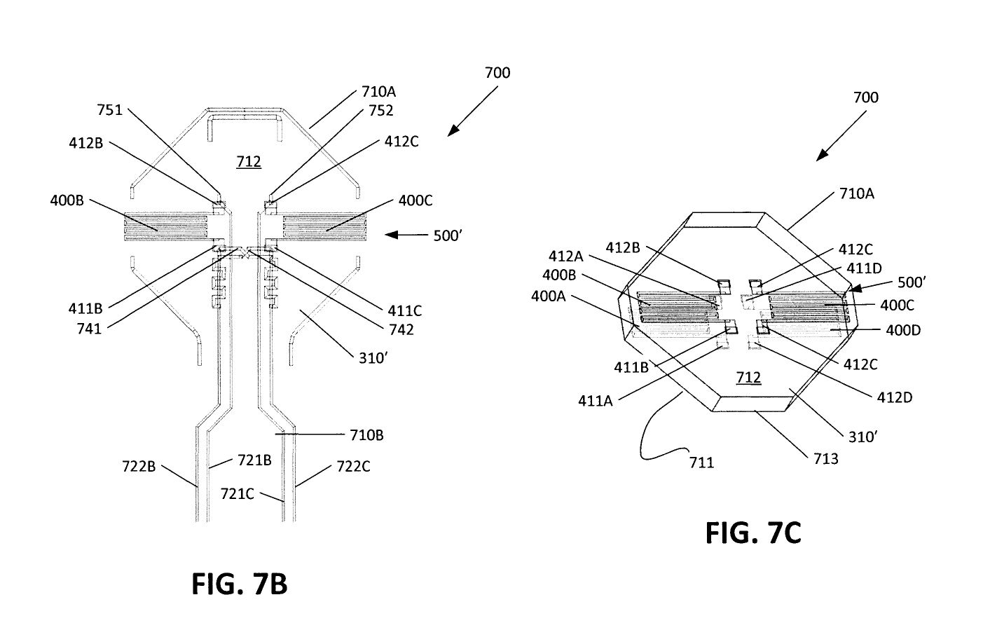

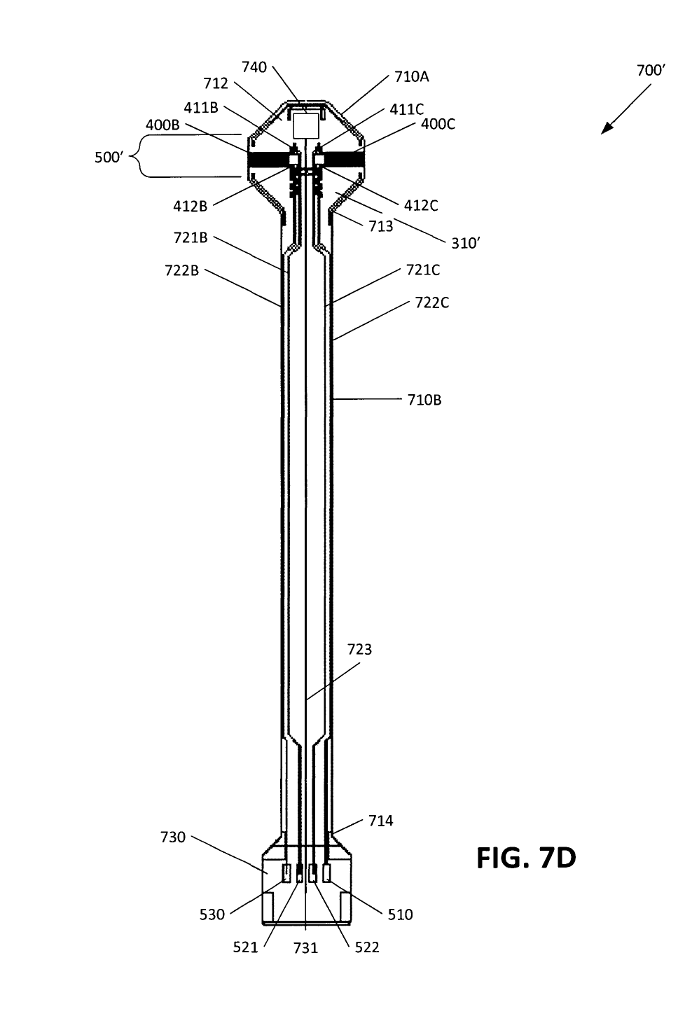

Referring now to FIG. 7A, there is illustrated an exemplary embodiment of the strain sensor 300, which exemplary embodiment is generally designated in FIG. 7A as 700, in accordance with an exemplary embodiment of the present invention. The strain sensor 700 comprises an exemplary embodiment of the substrate 310, generally designated as 310′ in FIG. 7A, and an exemplary embodiment of the Wheatstone bridge 500, generally designated as 500′ in FIGS. 7A through 7C. The substrate 310′ comprises a head portion 710A and a neck portion 710B. FIG. 7B illustrates a close-up plan view of the head portion 710A and a top portion of the neck portion 710B, and FIG. 7C illustrates a perspective, transparent view (for purposes of illustration) of the head portion 710A.

Referring to FIGS. 7A through 7C, the strain sensor 700 comprises the piezoresistors 400A, 400B, 400C, and 400D. The piezoresistors 400A and 400D are mounted on a first side 711 of the head portion 710A of the substrate 310′, and the piezoresistors 400B and 400C are mounted on a second side 712 of the head portion 710A of the substrate 310′ opposite the first side 711. As shown, the piezoresistor 400A on the first side 711 is aligned with the piezoresistor 400B on the second side 712 so that the distance between the center point of the piezoresistor 400A and the center point of the piezoresistor 400B is minimized to equal the thickness of the substrate 310′, and the piezoresistor 400D on the first side 711 is aligned with the piezoresistor 400C on the second side 712 so that the distance between the center point of the piezoresistor 400D and the center point of the piezoresistor 400C is minimized to equal the thickness of the substrate 710.

The piezoresistors 400A, 400B, 400C, and 400D are connected to form the

Wheatstone bridge 500′. The first terminal 411B of the piezoresistor 400B is connected to a first wire trace 721 B on the second side 712 of the head portion 710A and neck portion 710B. The second terminal 412B of the piezoresistor 400B is connected to a second wire trace 722B on the second side 712 of the head portion 710A and neck portion 710B, a top end 713 of which is connected to the head portion 710A. The first terminal 411C of the piezoresistor 400C is connected to a first wire trace 721 C on the second side 712 of the head portion 710A and neck portion 710B. The second terminal 412C of the piezoresistor 400C is connected to a second wire trace 722C on the second side 712 of the head portion 710A and neck portion 710B.

The Wheatstone bridge 500′ further comprises interconnect wire contacts (also referred to herein as “interconnects”) 741, 742, 751, and 752. The interconnect 741 couples the first terminal 411B of the piezoresistor 400B to the first terminal 411D of the piezoresistor 400D. The interconnect 742 couples the first terminal 411 C of the piezoresistor 400C to the first terminal 411 A of the piezoresistor 400A. The interconnect 751 couples the second terminal 412A of the piezoresistor 400A to the second terminal 412B of the piezoresistor 400B. The interconnect 752 couples the second terminal 412D of the piezoresistor 400D to the second terminal 412C of the piezoresistor 400C. In addition, the terminal 411A of the piezoresistor 400A is coupled to the terminal 411B of the piezoresistor 400B, and the terminal 411C of the piezoresistor 400C is coupled to the terminal 411D of the piezoresistor 400D. The interconnects are designed so that the leadouts between the legs of the Wheatstone bridge 500 are equal.

The strain sensor 700 further includes a connector 730 connected to the neck portion 710B of the substrate 310′ at a lower end 714 of the neck portion 710B. The connector 730 comprises the first output terminal 521, the second output terminal 522, the terminal 530, and the input terminal 510 of the Wheatstone bridge 500′. In the strain sensor 700, the terminals 510, 521, 522, and 530 may be mounting pad contacts for connection to external circuitry. The wire trace 721B is coupled to the first output terminal 521 of the output 520 of the Wheatstone bridge 500′. Thus, the second terminal 412A of the piezoresistor 400A and the second terminal 412B of the piezoresistor 400B are connected to the first output terminal 521 of the output 520 by the wire trace 721B. The wire trace 721C is coupled to the second output terminal 522 of the output 520 of the Wheatstone bridge 500′. Thus, the second terminal 412C of the piezoresistor 400C and the second terminal 412D of the piezoresistor 400D are connected to the second output terminal 522 of the output 520 by the wire trace 721C. The wire trace 722B is coupled to the terminal 530 of the Wheatstone bridge 500′. Thus, the first terminal 411B of the piezoresistor 400B and the first terminal 411D of the piezoresistor 400D are connected to the terminal 530 by the wire trace 722B. The wire trace 722C is coupled to the input terminal 510 of the Wheatstone bridge 500′. Thus, the first terminal 411A of the piezoresistor 400A and the first terminal 411C of the piezoresistor 400C are connected to the input terminal 510 by the wire trace 722C.

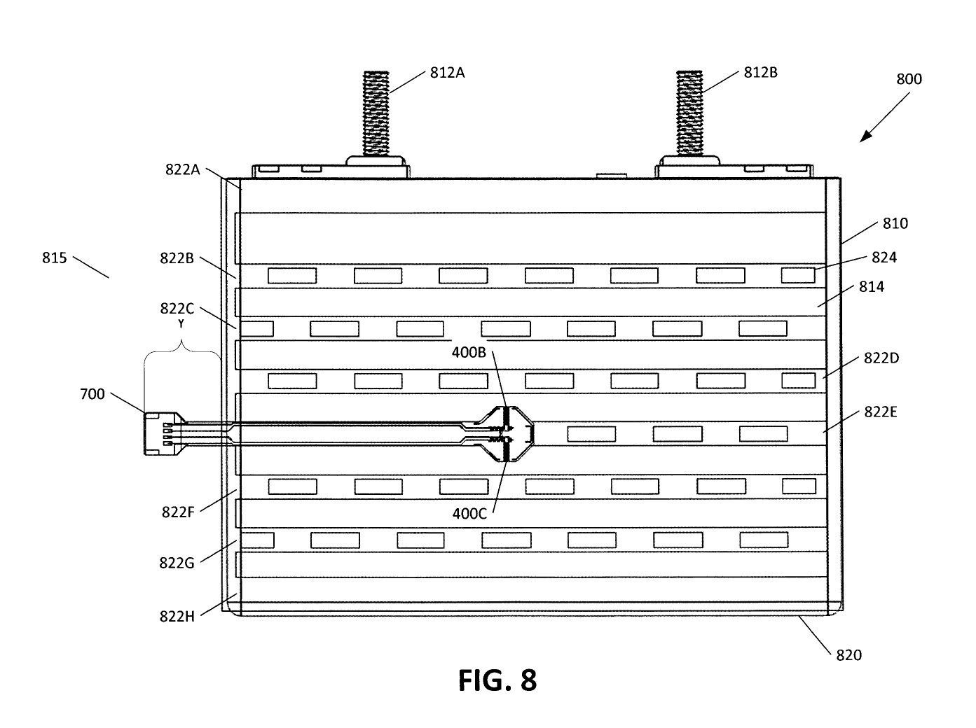

Referring now to FIG. 8, there is illustrated a battery system, generally designated as 800, in accordance with an exemplary embodiment of the present invention. The system 800 comprises a battery cell 810 comprising terminals 812A and 812B and a wall 814. Disposed over the wall 814 is a spacer 820. The spacer 820 comprises a plurality of horizontal members 822A through 822H which prevent the wall 814 of the battery cell 810 from making contact with the wall of an adjacent battery cell. Each of the plurality of horizontal members 822A through 822H comprises a plurality of cutouts 824 that allow air to flow between the battery cell 810 and the adjacent battery cell. The strain sensor 700 is positioned on the horizontal member 822E of the spacer 820 to make contact with a wall of the adjacent battery cell. In an exemplary embodiment, the spacer 820 is formed from plastic.

As seen in FIG. 8, the head 710A of the substrate 310′ is disposed on the horizontal member 822E of the spacer 820. The neck portion 710B of the substrate 310′ extends along the horizontal member 822E of the spacer 820 and beyond the edge 815 of the wall 814 of the battery cell 810. Thus, the connector 730 of the strain sensor 700 protrudes from beyond the edge 815 of the wall 814 of the battery cell 810 by a distance, Y. Such protrusion allows for the strain sensor 700 to be connected to external circuitry, such as the source 610, the amplifier 620, and the analysis module 650 of the system 600, which require space. Thus, the strain sensor 700 does not interfere with airflow between the cell 810 and an adjacent cell of the battery 800 and does not materially change the spacing of the cell 810 relative to other cells.

The strain sensor 700 is positioned on the horizontal member 822E of the spacer 820 so that the pair of the piezoresistors 400B and 400C straddle the horizontal member 822E of the spacer 820. Specifically, the strain sensor 700 is positioned so that the outside surface 312 of the substrate 310′ is in contact with the horizontal member 822E of the spacer 820. Thus, the piezoresistor 400B is positioned to be above but immediately adjacent to or touching the horizontal member 822A, and the piezoresistor 400C is positioned to be below but immediately adjacent to or touching the horizontal member 822A. The piezoresistors 400A and 400D have the same vertical positions relative to the horizontal member 822A as the piezoresistors 400B and 400C, respectively, although they are mounted on the inside surface 311 of the substrate 310′. Thus, the bottom of the piezoresistor 400A is vertically aligned with the bottom of the piezoresistor 400B, and the top of the piezoresistor 400D is vertically aligned with the top of the piezoresistor 400C. The piezoresistors 400A through 400D are vertically positioned relative to the horizontal member 822E of the spacer 820 so that they are subject to a high bending moment present in the wall of an adjacent battery cell. Specifically, the piezoresistors 400A through 400D are so positioned so that they are located at the maximum bending stress on the wall of the adjacent battery cell and thus the maximum stress that is recognized by the cell wall. Thus, the position of the piezoresistors 400A through 400D provides the best indication of the contraction and expansion of, and distance travelled by, the adjacent battery cell wall.

In an exemplary embodiment of the system 600, generally designated as 600′ in FIG. 6B, the strain sensor 700 is used as a specific embodiment of the Wheatstone bridge 500. In such embodiment, the input 510 of the strain sensor 700 is connected to the signal source 610; the terminal 530 of the strain sensor 700 is connected to ground 690; the output 521 of the strain sensor 700 is connected to the input 621 of the amplifier 620; and the output 522 of the strain sensor 700 is connected to the input 622 of the amplifier 620. The system 600′ may be used to measure the strain detected by the strain sensor 700 when affixed to the wall 814 of the battery cell 810. Thus, the system 600′ may be used to calculate a SOH or SOC of the battery cell 810 based on strain measured by the strain sensor 700.

With respect to FIG. 6B, the elongated neck portion 710B of the substrate 310′ of the strain sensor 700 allows for the signal source 610, the amplifier 620, and the analysis module 650 of the system 600 to be located outside of the space between cells, e.g., the space between the cell 810 on which the strain sensor 700 is mounted and an adjacent cell. By locating these components outside such space, the profile of the battery 800 containing the cell 810 need not change on account of the strain sensor 700 being mounted therein.

In an exemplary embodiment, the strain sensor 700 further comprises a temperature sensor for measuring a temperature of the wall 814 of the battery cell 810. Referring now to FIG. 7D, there is illustrated an exemplary alternative embodiment of the strain sensor 700, generally designated in the figure as 700′, in accordance with an exemplary embodiment of the present invention. The strain sensor 700′ includes all of the features and components as the strain sensor 700 and further includes a temperature sensor 740 disposed in the head portion 710A and a further output terminal 731 connected to the temperature sensor 740 by a wire trace 723.

In another exemplary embodiment of the system 600′, generally designated as 600″ in FIG. 6C, the strain sensor 700′ is used as a specific embodiment of the Wheatstone bridge 500 and for measuring temperature. In such embodiment, the input 510 of the strain sensor 700′ is connected to the signal source 610; the terminal 530 of the strain sensor 700′ is connected to ground 690; the output 521 of the strain sensor 700′ is connected to the input 621 of the amplifier 620; and the output 522 of the strain sensor 700′ is connected to the input 622 of the amplifier 620. Similar to the system 600′, the system 600″ may be used to measure the strain detected by the strain sensor 700 when affixed to the wall 814 of the battery cell 810. Thus, the system 600″ may be used to calculate a SOH or SOC of the battery cell 810 based on strain measured by the strain sensor 700.

The system 600″ includes all of the components of the system 600. However, the system 600″ comprises an exemplary alternative embodiment of the module 640, generally designated in FIG. 6C as 640′. The module 640′ is similar to the module 640 but further includes an input 643 connected to the output 731 of the strain sensor 700′. The module 640′ receives an indication of temperature sensed by the temperature sensor 740 at the input 643. The module 640′ also receives the total strain ε₁−ε₂+ε₄−ε₃ at an input 641 and the mechanical battery model 645 at an input 642. Using the total strain ε₁−ε₂+ε₄−ε₃, the temperature indication, and the mechanical battery model 645, the module 640′ calculates a SOC and/or a SOH for the battery cell 210A. Although the strain sensor 700′ is designed to be insensitive to temperature, errors may arise because of fabrication errors. The module 640′ uses the temperature indication to compensate for such residual error to improve the calculation of the SOC and/or SOH. The module 640′ provides the calculated SOC and/or SOH at an output 644.

In an exemplary alternative embodiment, the module 630 further includes and input 636 that is connected to the output 731 of the strain sensor 700′ for receiving the indication of temperature. The module 630 adjusts the calculated strain based on the received indication of temperature. In such embodiment, the module 640′ does not use the indication of temperature in the calculation of SOC and/or SOH.

The strain sensor 700, 700′ is advantageous over conventional strain sensors for measuring strain in a battery cell wall for several reasons. First, the substrate 310′ of the strain sensor 700, 700′ is ultrathin, e.g., less than 100 μm. Because of its thinness, the strain sensor 700, 700′ may be disposed on the outside wall 814 of the battery cell 810 without interfering with the spacer 820 or an adjacent battery wall. The spacer 820 function of preventing the outside wall 814 of the battery cell 810 from making contact with the wall of an adjacent battery wall is unimpeded. Second, the voltage output of the strain sensor 700 is not sensitive to temperature change. Thus, the system 600′ senses voltage from the strain sensor 700 and calculates strain parameters independently from temperature measurements. Furthermore, exemplary embodiments of the strain sensor 700, i.e., the strain sensor 700′, include an integrated temperature sensor that provides a temperature indication that may be used by the system 600″ to calculate SOH and/or SOC for the battery. Fourth, the strain sensor 700, 700′ is robust against mounting and assembly variations such as different adhesive, pretension forces, etc.

An exemplary embodiment of the strain sensor 700 was constructed and tested during a charging and discharging cycle of an exemplary embodiment of the battery cell 810 using the system 600′. During the charging and discharging cycle, the battery cell 810, the temperature of the battery cell 810 varied within a range of 0.4 degrees Celsius. The system 600′ measured voltage over a range of about 1 mV, which corresponded to 35e-6 bending strain. The corresponding calculation indicated that 35e-6 bending strain corresponded to about 7 μm in deflection of the surface of the battery cell 810. These data points form an exemplary embodiment of the mechanical data model 645.

Measured voltage and calculated strain over time are illustrated in a plot shown in

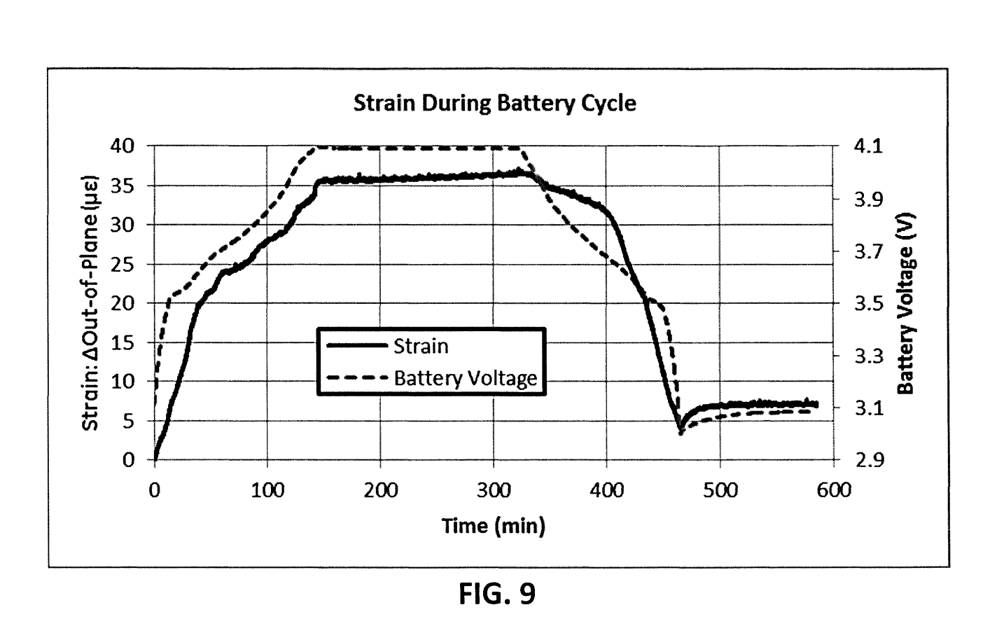

FIG. 9, in accordance with an exemplary embodiment of the present invention. The voltage curve shows the voltage of the battery cell 810 during charge and discharge. The rise in voltage was indicative of charging, and the decrease in voltage was indicative of discharging. Between the charge and discharge, there was a three-hour dwell to let the cell 810 equilibrate. The strain curve shows the calculated strain performed by the analysis module 650. The slope of the strain signal can provide useful information on the SOC where the voltage curve shows minimal change (near full charge) or when it drops rapidly (near full discharge). The SOC is optimally determined by voltage and current, but current cannot be measured on a cell-by-cell basis due to the series connection of the cells. Thus, the slope of the strain signal provides information regarding the SOC.

In an exemplary embodiment, the modules 630 and 640 of the systems 600, 600′, and 600″ are performed by a computer system comprising a processor and a memory storing software instructions. Specifically, it is to be understood that, in an exemplary embodiment, the analysis module 650 is performed by a general purpose computer which is programmed with computer instructions, e.g., software, stored in a tangible computer-readable medium located internally to or externally from the general purpose computer. Additionally, the calibration factors 635 and the mechanical battery module 645 may be stored on such tangible computer-readable medium. When executed by the computer, the computer instructions cause the computer to perform the functionality of the analysis module 650, specifically, the modules 630 and 640, described above.

As used herein, a “computer-readable medium” may be any available computer storage medium that can be accessed by the computer. Such computer storage medium includes both volatile and nonvolatile and removable and non-removable media implemented in any method or technology for storage of information such as computer-readable software instructions, data structures, program modules, information on the patient and medical treatment, or other data. Such computer storage media include a magnetic media, optical media, magneto-optical media, and solid-state media.

Magnetic media include magnetic cassettes, magnetic tape, magnetic disk storage (computer hard drive), or other magnetic storage devices. Optical media include optical discs, such as compact disc read-only memory (CDROM), digital versatile disks (DVD), or other optical disk storage. Magneto-optical media include magneto-optical drives. Solid-state memory includes random access memory (RAM), read-only memory (ROM), Electrically-Erasable Programmable Read-Only Memory (EEPROM), flash memory, or other memory technology.

These and other advantages of the present invention will be apparent to those skilled in the art from the foregoing specification. Accordingly, it is to be recognized by those skilled in the art that changes or modifications may be made to the above-described embodiments without departing from the broad inventive concepts of the invention. It is to be understood that this invention is not limited to the particular embodiments described herein, but is intended to include all changes and modifications that are within the scope and spirit of the invention.

What is claimed is:

1. A strain sensor comprising:
a thin, flexible substrate;
a plurality of piezoresistors deposited on the substrate, the plurality of piezoresistors connected to form a circuit that is sensitive to out-of-plane strain and insensitive to in-plane strain and changes in temperature;
an input for receiving a voltage signal; and
an output for providing an output voltage signal from the plurality of piezoresistors.

2. The strain sensor of claim 1, wherein the plurality of piezoresistors are connected together to form a Wheatstone bridge.

3. The strain sensor of claim 1, wherein the plurality of piezoresistors have equal resistances.

4. The strain sensor of claim 3, wherein the substrate comprises a first side and a second side, and the plurality of piezoresistors comprises first, second, third, and fourth piezoresistors.

5. The strain sensor of claim 4, wherein the first and fourth piezoresistors are mounted on the first side of the substrate, and the second and third piezoresistors are mounted on the second side of the substrate, and wherein the first and second piezoresistors are disposed on the substrate opposite one another, and the third and fourth piezoresistors are disposed on the substrate opposite one another.

6. The strain sensor of claim 5, wherein a distance between the first and second piezoresistors is equal to a thickness of the substrate, and a distance between the third and fourth piezoresistors is equal to a thickness of the substrate.

7. The strain sensor of claim 5, wherein the first, second, third, and fourth piezoresistors are disposed on the substrate in a direction of a high bending moment.

8. The strain sensor of claim 5, wherein a distance between the second and third piezoresistors is equal to or slightly larger than a horizontal member about which the second and third piezoresistors are configured to be disposed.

9. The strain sensor of claim 8, wherein the second and third piezoresistors are spaced to be disposed under the horizontal member and to extend outwardly from the horizontal member.

10. The strain sensor of claim 1, wherein each of the plurality of piezoresistors is formed from platinum, silicon, polysilicon, or a conductive ink, and the substrate is formed from polyimide, mylar, or an insulated metal.

11. The strain sensor of claim 1, wherein a coefficient of expansion of the substrate matches a coefficient of expansion of a battery cell on which the strain sensor is to be mounted.

12. A system for monitoring a state of a battery cell, the system comprising:
a source of voltage;
a strain sensor comprising:
a thin, flexible substrate;
a plurality of piezoresistors mounted on the substrate, the plurality of piezoresistors connected to form a circuit that is sensitive to out-of-plane strain and insensitive to in-plane strain and changes in temperature;
an input for receiving a voltage from the source of voltage; and
an output for providing an output voltage signal from the plurality of piezoresistors; and
a signal analysis module configured for:
receiving a voltage signal based on the output voltage signal provided at the output of the strain sensor; and
calculating a state of charge or a state of health of a battery cell based on the received voltage signal.

13. The system of claim 12, further comprising an amplifier configured for receiving the output voltage signal, amplifying the received output voltage signal, and providing the amplified output voltage signal to the signal analysis module as an amplified input voltage signal, wherein the voltage signal received by the signal analysis module is the amplified input voltage signal.

14. The system of claim 12, wherein the signal analysis module comprises:
a first module configured for converting the amplified input voltage signal to strain; and
a second module configured for converting the strain to an indication of the state of charge or the state of health of the battery cell.

15. The system of claim 14, wherein the first module is configured for converting the amplified input voltage signal to strain based on one or more calibration factors of the battery cell.

16. The system of claim 15, wherein the one or more calibration factors comprises a gauge factor for the plurality of piezoresistors.

17. The system of claim 14, wherein the second module is configured for converting the strain to an indication of the state of charge or the state of health of the battery cell based on a mechanical battery model.

18. The system of claim 12, wherein the plurality of piezoresistors have equal resistances.

19. The system of claim 12, wherein the substrate of the strain sensor comprises a first side and a second side and the plurality of piezoresistors comprises first, second, third, and fourth piezoresistors.

20. The system of claim 19, wherein the first and fourth piezoresistors are mounted on the first side of the substrate, and the second and third piezoresistors are mounted on the second side of the substrate, and wherein the first and second piezoresistors are disposed on the substrate opposite one another, and the third and fourth piezoresistors are disposed on the substrate opposite one another.

21. The system of claim 20, wherein a distance between the first and second piezoresistors is equal to a thickness of the substrate, and a distance between the third and fourth piezoresistors is equal to a thickness of the substrate.

22. The system of claim 20, wherein the first, second, third, and fourth piezoresistors are disposed on the substrate in a direction of a high bending moment.

23. The system of claim 20, wherein a distance between the second and third piezoresistors is equal to or slightly larger than a horizontal member about which the second and third piezoresistors are configured to be disposed.

24. The system of claim 23, wherein the second and third piezoresistors are spaced to be disposed under the horizontal member and to extend outwardly from the horizontal member.

25. The system of claim 12, wherein the signal analysis module is further configured for calculating strain based on the received voltage signal, and wherein the calculation of the state of charge or the state of health of the battery cell is based on the calculated strain.

26. The system of claim 12, wherein the calculation of the state of charge or the state of health of the battery cell is further based on a temperature sensed by one of the plurality of piezoresistors.

27. The system of claim 12, wherein the strain sensor further comprises a temperature sensor, and the calculation of the state of charge or the state of health of the battery cell is further based on a temperature sensed by the temperature sensor.

28. A battery comprising:
a spacer comprising at least one horizontal member;
a first battery cell comprising a first wall;
a second battery cell comprising a first wall spaced from the first wall of the first battery cell by the spacer; and
a strain sensor, at least a portion of which is disposed on the first wall of the first battery cell, the strain sensor comprising:
a thin, flexible substrate;
a plurality of piezoresistors mounted on the substrate, the plurality of piezoresistors connected to form a circuit that is sensitive to out-of-plane strain and insensitive to in-plane strain and a change in temperature;
an input for receiving a voltage signal; and
an output for providing an output voltage signal from the plurality of piezoresistors.

29. The battery of claim 28, wherein the plurality of piezoresistors of the strain sensor are disposed between the first wall of the first battery cell and the at least one horizontal member of the spacer.

30. The battery of claim 28, wherein the substrate of the strain sensor comprises a first side and a second side and the plurality of piezoresistors comprises first, second, third, and fourth piezoresistors.

31. The battery of claim 30, wherein the first and fourth piezoresistors are mounted on the first side of the substrate, and the second and third piezoresistors are mounted on the second side of the substrate, and wherein the first and second piezoresistors are disposed on the substrate opposite one another, and the third and fourth piezoresistors are disposed on the substrate opposite one another.

32. The battery of claim 31, wherein at least a portion of the first side of the substrate of the strain sensor and the first and fourth piezoresistors are in contact with the first wall of the first battery cell, and a portion of the second side of the substrate of the strain sensor is in contact with the at least one horizontal member of the spacer.

33. The battery of claim 32, wherein the at least one horizontal member of the spacer is disposed between the second and third piezoresistors of the strain sensor.

34. The battery of claim 28, further comprising a signal source configured to supply a signal to the strain sensor.

35. The battery of claim 34, wherein the signal comprises one of a DC voltage, an AC signal, and a series of pulses.

36. The battery of claim 28, wherein the substrate of the strain sensor has a coefficient of expansion that is equal to a coefficient of expansion of the first wall of the first battery cell.

37. The battery of claim 28, wherein a centerline of the substrate of the strain sensor is offset from a neutral axis of the first battery cell.
